(19) United States
(12) Patent Application Publication
(10) Pub. No.: US 2009/0108408 A1
(43) Pub. Date: Apr. 30, 2009

(54) Method for Trapping Implant Damage in a Semiconductor Substrate

(75) Inventors: Victor Moroz, Saratoga, CA (US); Dipankar Pramanik, Saratoga, CA (US)

Correspondence Address: SYNOPSYS, INC. C/O HAYNES BEFFEL & WOLFELD LLP, P.O. BOX 366, HALF MOON BAY, CA, 94019, US

(73) Assignee: SYNOPSYS, INC., Mountain View, CA (US)

(21) Appl. No.: 11/926,485

(22) Filed: Oct. 29, 2007

(51) Int. Cl. H01L 21/322; H01L 29/32

(52) U.S. Cl. 257/617; 438/473; 257/E29.107; 257/E21.318

(57) ABSTRACT

A method for minimizing the effects of defects produced in a implantated area of a crystal lattice during dopant implantation in the lattice. The method begins with the step of implanting a trap layer of trap atoms, the trap atoms having a size less than that of the lattice member atoms. After implantation, the lattice is annealed for a time sufficient for interstitial defect atoms to be emitted from the defect area. In that manner, energetically stable pairs are formed between trap atoms and emitted interstitial atoms.

### BACKGROUND OF THE INVENTION

The present invention relates to the field of semiconductor fabrication. In particular, it relates to the fabrication of field effect transistors (FETs), involving the formation of semiconductor materials of selected conductivity is carried on by implantation of dopants.

Fabrication of metal oxide semiconductor (MOS) FETs requires the formation of source and drain regions in a substrate of generally pure silicon (Si). The Si is provided in the form of a wafer, grown as a single crystal. Zones of the Si lattice are converted into regions of N or P conductivity by the addition of donor-type dopants, such as arsenic, for N regions and acceptor-type dopants, such as boron, for P regions. These dopants are generally introduced by ion bombardment, in which ionized dopant atoms are energized and fired at the lattice, penetrating the crystal structure to a depth largely dependent on the bombardment energy and the ion mass.

It can be immediately gathered that such bombardment introduces crystal damage, in which lattice atoms are knocked out of lattice sites, while at the same time a certain number of the newly-introduced atoms will likewise come to rest in positions outside the lattice positions. Such out-of-position phenomena are termed defects. A vacant lattice site is termed a vacancy defect, while an atom located at a non-lattice site is referred to as an interstitial defect. The restorative method generally employed in the art consists of annealing the crystal, applying heat to the lattice to mildly energize the atoms, allowing them to work themselves back into the lattice structure, which provides the arrangement having the lowest overall energy level.

### SUMMARY OF THE INVENTION

An aspect of the claimed invention is a method for minimizing the effects of defects produced in an implanted area of a crystal lattice during dopant implantation in the lattice. The method begins with the step of implanting a trap layer of trap atoms, the trap atoms having a size less than that of the lattice member atoms. After implantation, the lattice is annealed for a time sufficient for interstitial defect atoms to be emitted from the defect area. In that manner, energetically stable pairs are formed between trap atoms and emitted interstitial atoms.

### BRIEF DESCRIPTION OF THE DRAWINGS

FIG. 1 illustrates an FET transistor of the prior art, including damage caused by dopant implantation.

FIG. 2 depicts the effects of annealing a silicon substrate after dopant implantation as practiced in the prior art, after time periods of 3, 10, 30 and 60 seconds.

FIGS. 3a and 3b depict the defects produced during an implantation step, and the effect of annealing.

FIGS. 4a and 4b illustrate the effect of the claimed invention on defects produced during implantation.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

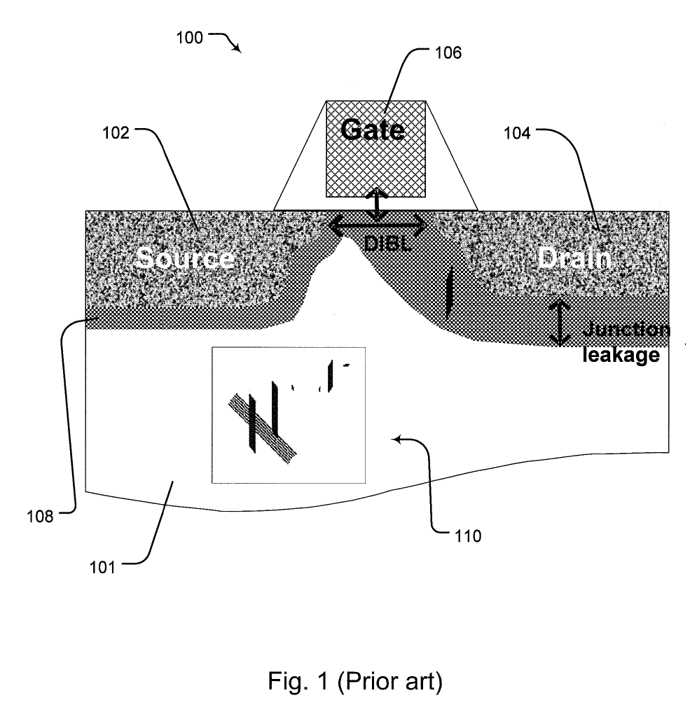

The problem addressed by the present disclosure is seen in FIG. 1, which depicts a typical MOSFET 100 after undergoing ion implantation. The transistor is formed on a silicon substrate 101 and includes source 102, drain 104 and gate 106. The depletion layer 108 adjacent each electrode is well known in the art.

Primary leakage modes of such a device are shown. These leakage paths are of great concern to designers, as they account for significant power consumption when considered in terms of multi-million transistor arrays. Leakage modes include junction leakage across the depletion layer, gate leakage across the gate dielectric from the channel to the gate electrode, and drain-induced barrier lowering (DIBL), which, as the name implies, causes the depletion layer in the vicinity of the drain end of the channel to widen and the source-to-channel barrier to lower.

The side effects of ion implantation can be seen in the defects 110 scattered throughout the substrate. An important distinction is noted on the drawing: Defects lying outside the depletion layer are harmless in terms of their effect on transistor performance or leakage. Defects present conduction paths, which are completely harmless when isolated in the substrate, removed from the depletion layer, but within that layer a defect offers a low-resistance bridge, effectively creating a short circuit across the depletion layer. A different leakage mechanism results from the tendency of defects to introduce energy levels within the bandgap, drastically increasing the generation of electron-hole pairs, further contributing to the flow of current across the junction.

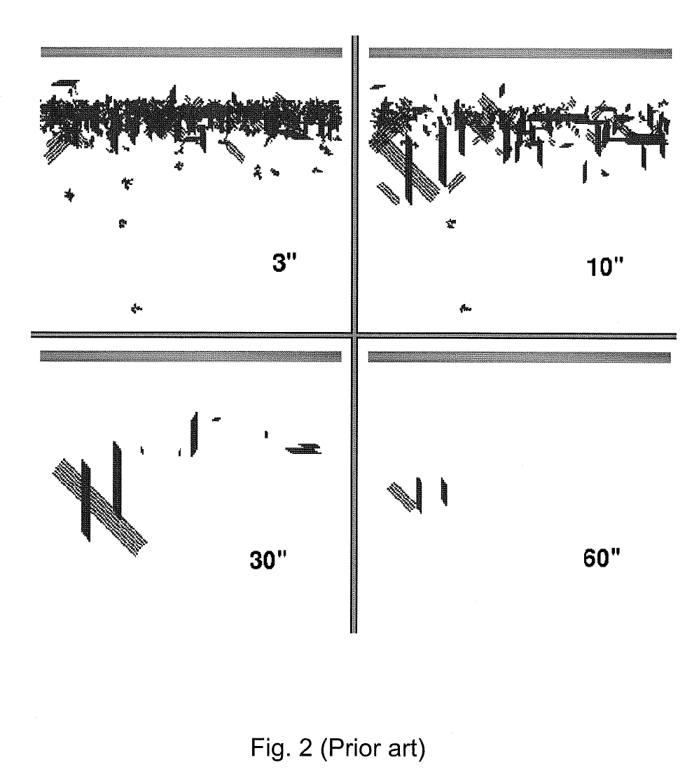

Defects are generally treated by annealing, exposing the wafer to sustained heating over a period of time sufficient to allow atoms to migrate to positions that result in the lowest energy state that can be achieved for a given structure under the circumstances. FIG. 2 depicts a typical substrate after ion implantation, showing defect levels at four times, 3 seconds, 10 seconds, 30 seconds and 60 seconds. The upper left portion of the drawing, depicting the situation 3 seconds after implantation reveals a large number of defects, generally at a depth corresponding to the implantation depth of the dopant atoms. A layer of clean silicon layer forms above the defects, due to epitaxial recrystallization of the amorphized silicon during the post-implant anneal. The heat sufficiently energizes atoms lying outside lattice sites, so they migrate to lattice sites, or to the surface of the layer, or they join with other defects. Each of those results produces a lower energy state than that of the single defect. These effects can be seen in the upper right portion of the diagram, showing the situation after 10 seconds of annealing. As can be seen, the total number of defects has been reduced, and some defects have grown in size. After 30 seconds, as shown in the lower left drawing, the number of defects has dramatically decreased, leaving several large defects and only a few small ones. Finally, after 60 seconds, only a very small number of defects remains, and the large defects present at 30 seconds have reduced in size. It will be understood, however, that even the few remaining defects, if located within the depletion zone, as seen in FIG. 1, can cause serious problems, as such defects can lead to a short circuit, not simply a small leakage current.

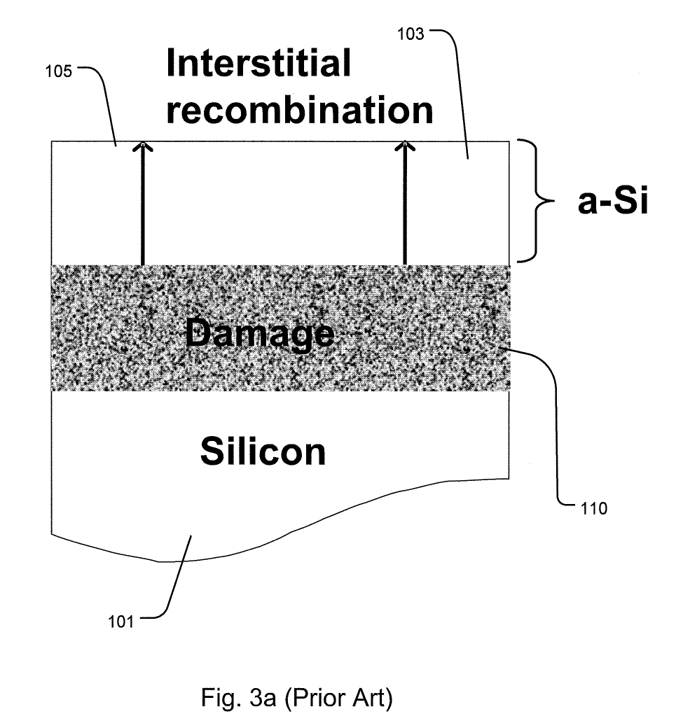

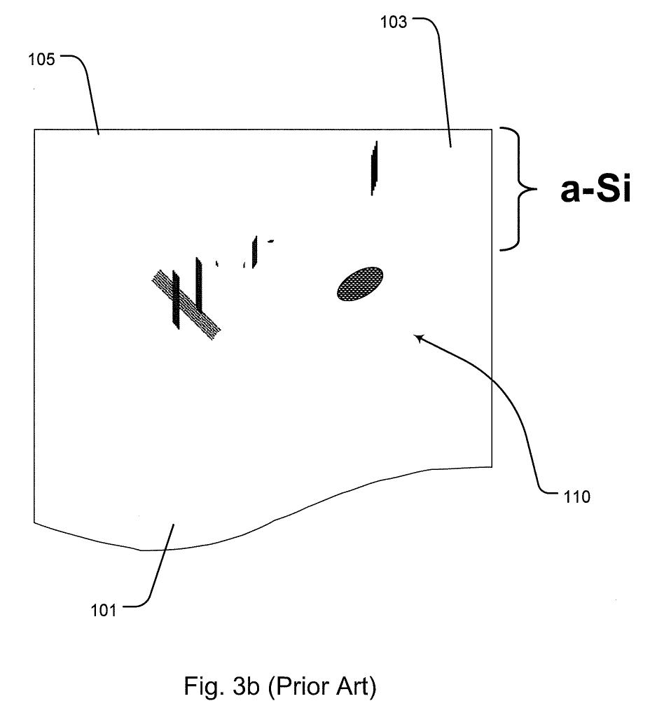

Up to the present, the art has depended on the mechanism shown in FIGS. 3a and 3b to deal with defects. As seen in FIG. 3a, the implantation process creates a damaged area where defects 110 predominate, with largely undamaged substrate 101 lying below that level. A zone of amorphous silicon (a-Si) 103 lies between the damage zone and the silicon surface 105. The a-Si is a further side effect of the implantation, as the high-energy atoms passing through the lattice largely destroy the lattice structure. With annealing, interstitial defects tend to migrate to the surface, as shown, and the a-Si reconstitutes itself into a lattice structure, including the interstitial Si atoms displaced by the implantation, which form new lattice sites at the surface 105. The result of annealing, shown in FIG. 3a, largely eliminates defects and restores the lattice structure, but the defects that do remain, however, tend to be much larger than the individual vacancy and interstitial defects that appear immediately after implantation. As noted above, individual defects coalesce to form line defects, area defects and interstitial loops.

The mechanism of FIGS. 3a and 3b can work perfectly, provided one can assume that the distance from the level of the defects 110 to the surface 105 is larger than the depth of the depletion layer. Modern deep sub-micron semiconductor designs call that assumption into question, creating a strong probability that defects will remain in the depletion layer to cause problems, as seen in FIG. 1. Note in FIG. 3b, for example, the line defect shown near the surface 105. Such a defect will most likely produce problems when the transistor is formed.

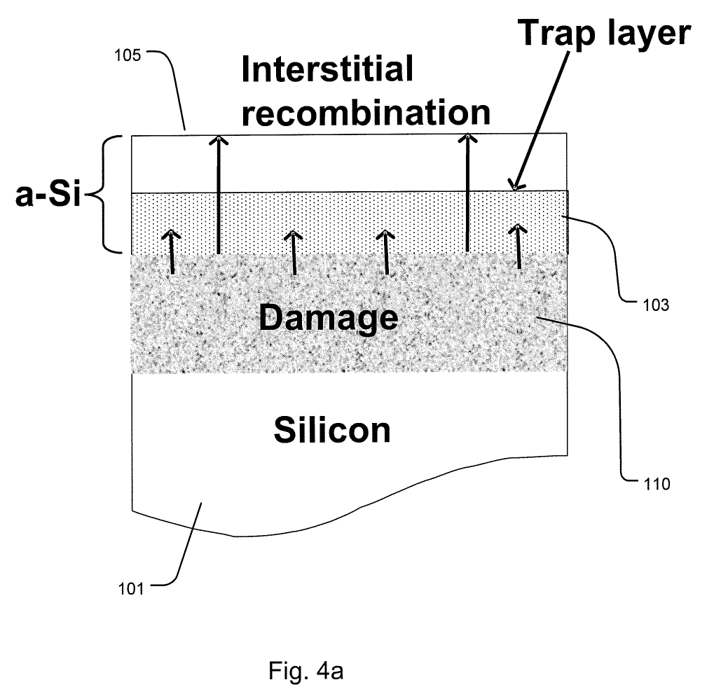

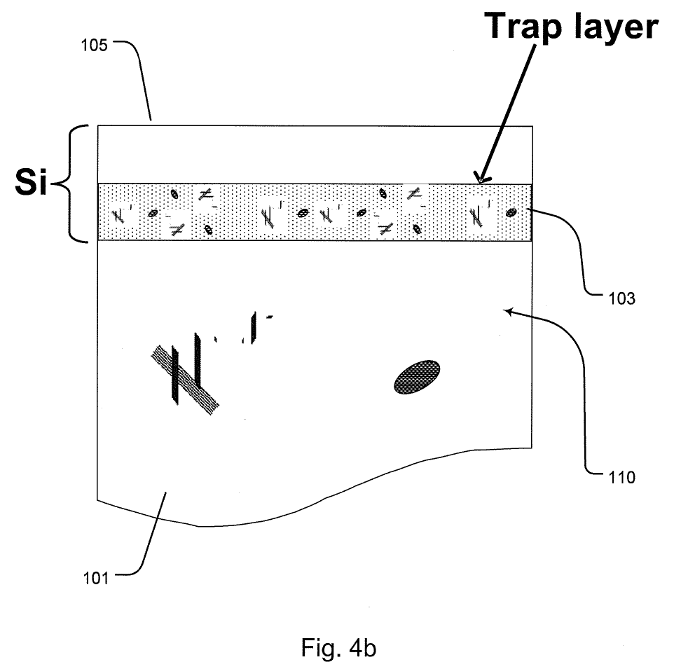

A solution is shown in FIGS. 4a and 4b, where a trap layer 103 is added by implantation after the dopant implantation, with the implantation energy adjusted to produce implantation at a depth slightly less than that of the dopant, as shown. Atoms chosen for implantation in the trap layer should be smaller than those that make up the lattice, so that the trap layer produces tensile stress in the lattice as a whole. Then, when an interstitial atom from the defects 110 penetrates the trap layer, the combination of the stress produced by the interstitial and that produced by neighboring trap atom is less than that existing either with the trap atoms alone or the interstitial atoms alone. The trap layer thus becomes an energetically favorable location for interstitials, as an energy cost is required for the interstitial to move either toward the surface or back into the defect area. The trap layer effectively retains interstitials, blocking their movement toward the substrate surface.

The post-annealing result is seen in FIG. 4b, where a number of large defects remain deep within the substrate, but numbers of small and individual defects are captured within the trap layer. No defects at all are in the area between the trap layer and the substrate surface, and this result allows a designer to position a trap layer sufficiently deep in the substrate to ensure that no defects exist within a depletion layer, no matter how small the semiconductor lithographic feature size may become.

As noted, the primary criterion for selecting atoms to be implanted in the trap layer is the atomic size. The trap layer implants must impose a tensile stress on the lattice in order to perform the trap function. Thus, in a silicon lattice, an atom occurring before silicon in the periodic table would be sufficient. Several other considerations enter the design picture, however. One factor is the stability of the trap atoms in combination with dopant atoms. In one embodiment, arsenic atoms are employed in high dosage to form nMOSFETs, and germanium preamorphization implants (PAI) are employed for form pMOSFETs. In such environments, it has been found that carbon, nitrogen and fluorine both provide good results as trap layer atoms. Another point to consider is the stability of trap atoms in a lattice structure. Sodium, for example, would seem to offer good properties as a trap atom, but the fact that it carries an electrical charge, making it mobile in a lattice at room temperature, makes it a poor choice. The latter point leads to the further requirement that a trap implant must form an electrically neutral pair with the interstitial being trapped.

A further consideration is the location of the trap layer. It has been found that the trap layer should be located immediately next to the implant damage region to be effective. Thus, a designer would take that fact, coupled with the lithographic feature size and the depletion layer, into consideration.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

1. A method for minimizing the effects of defects produced in an implanted area of a crystal lattice during dopant implantation in the lattice, comprising the steps of
implanting a trap layer of trap atoms, the trap atoms selected to facilitate formation of energetically stable pairs with lattice member atoms;
annealing the lattice for a time sufficient for interstitial defect atoms to be emitted from the implant-induced defect area;
whereby energetically stable pairs are formed between trap atoms and emitted interstitial atoms.

2. The method of claim 1, wherein the trap atoms are electrically neutral.

3. The method of claim 1, wherein the pairs formed by trap atoms and emitted interstitial atoms are electrically neutral.

4. The method of claim 1, wherein the lattice-member atoms are silicon, and the trap atoms are selected from the group including carbon, nitrogen, and fluorine.

5. The method of claim 1, wherein the trap atoms are smaller than silicon atoms.

6. The method of claim 1, wherein the annealing step produces epitaxial recrystallization of amorphized silicon, and the trap atoms are implanted at a location selected to lie between a surface of the crystal lattice and the expected location of implant damage remaining after the annealing step.

7. A method for fabricating a semiconductor formed on a crystal lattice substrate, having N-type and P-type regions, with a channel between the regions and a gate positioned above the channel and a depletion layer adjacent each region wherein the effects of defects produced in an implanted area of a crystal lattice during dopant implantation in the lattice are minimized, comprising the steps of
implanting a trap layer of trap atoms, the trap atoms selected to facilitate formation of energetically stable pairs with lattice member atoms;
annealing the lattice for a time sufficient for interstitial defect atoms to be emitted from the implant-induced defect area;
whereby energetically stable pairs are formed between trap atoms and emitted interstitial atoms.

8. The method of claim 7, wherein the trap atoms are electrically neutral.

9. The method of claim 7, wherein the pairs formed by trap atoms and emitted interstitial atoms are electrically neutral.

10. The method of claim 7, wherein the lattice-member atoms are silicon, and the trap atoms are selected from the group including carbon, nitrogen, and fluorine.

11. The method of claim 7, wherein the trap atoms are smaller than silicon atoms.

12. The method of claim 7, wherein the annealing step produces epitaxial recrystallization of amorphized silicon, and the trap atoms are implanted at a location selected to lie between a surface of the crystal lattice and the expected location of implant damage remaining after the annealing step.

13. The method of claim 7, wherein the annealing step produces epitaxial recrystallization of amorphized silicon, and the trap atoms are implanted at a location selected to lie between the depletion layer and the expected location of implant damage remaining after the annealing step.

14. The method of claim 7, wherein the trap atoms are introduced in a location that at least partially overlaps the depletion region, and wherein neither the pairs introduci eep levels into the bandgap.

15. A semiconductor formed on a crystal substrate, having N-type and P-type regions, with a channel between the regions and a gate positioned above the channel, with a depletion layer adjacent each region, comprising a trap layer of trap atoms, the trap atoms having a size less than that of the lattice member atoms, the trap layer being located outside the depletion layer and the trap layer including energetically stable pairs of trap atoms and interstitial defect atoms, the defect atoms having been emitted from the area of the substrate damaged by the implantation of dopant during processing of the same.

16. The semiconductor of claim 15, wherein the trap atoms are electrically neutral.

17. The semiconductor of claim 15, wherein the pairs formed by trap atoms and emitted interstitial atoms are electrically neutral.

18. The semiconductor of claim 15, wherein the lattice-member atoms are silicon, and the trap atoms are selected from the group including carbon, nitrogen, and fluorine.
